(19) United States
(12) Patent Application Publication
(10) Pub. No.: US 2025/0233094 A1
(43) Pub. Date: Jul. 17, 2025

(54) SEMICONDUCTOR PACKAGES

(71) Applicant: SAMSUNG ELECTRONICS CO., LTD., Suwon-si (KR)

(72) Inventors: Kyung Don Mun, Suwon-si (KR); Hyeonseok Lee, Suwon-si (KR)

(21) Appl. No.: 18/809,746

(22) Filed: Aug. 20, 2024

(30) Foreign Application Priority Data
Jan. 15, 2024 (KR) 10-2024-0006041

(51) Int. Cl. H01L 23/00; G02B 6/42; H01L 23/13; H01L 23/48; H01L 23/538; H01L 25/16; H10B 80/00

(52) U.S. Cl. CPC H01L 24/08; G02B 6/4274; H01L 23/13; H01L 23/481; H01L 23/5386; H01L 24/05; H01L 24/06; H01L 24/16; H01L 25/167; H01L 24/32; H01L 24/73; H01L 24/97; H01L 2224/05541; H01L 2224/0603; H01L 2224/08145; H01L 2224/08225; H01L 2224/16225; H01L 2224/32225; H01L 2224/73204; H01L 2224/97; H01L 2924/1431; H01L 2924/1436; H10B 80/00

(57) ABSTRACT

A semiconductor package includes a first substrate including a first edge region, a center region, and a second edge region arranged side by side in a first direction, and having a cavity in the first edge region, an optical die disposed in the cavity of the first substrate, a first semiconductor chip including an electronic integrated circuit region therebelow and disposed on the first substrate and the optical die, and a plurality of second semiconductor chips disposed on the second edge region of the first substrate, wherein the electronic integrated circuit region of the first semiconductor chip is disposed on the optical die and is electrically connected to the optical die.

### CROSS-REFERENCE TO RELATED APPLICATIONS

This U.S. non-provisional patent application claims priority under 35 U.S.C. § 119 to Korean Patent Application No. 10-2024-0006041, filed on Jan. 15, 2024, in the Korean Intellectual Property Office, the entire contents of which are hereby incorporated by reference.

### BACKGROUND

Demand for miniaturization and high speed of electronic devices has increased. Accordingly, research is actively conducted to replace signal transmission through conventional metal wiring with signal transmission using optical signals. A semiconductor package including an optical integrated circuit with an integrated light source and an optical coupling element may be used to transmit the optical signals.

### SUMMARY

Some implementations according to the present disclosure provide semiconductor packages with improved operation speed and optimized performance.

A semiconductor package according to some implementations of the present disclosure includes a first substrate including a first edge region, a center region, and a second edge region arranged side by side in a first direction, and having a cavity in the first edge region, an optical die disposed in the cavity of the first substrate, a first semiconductor chip including an electronic integrated circuit region therebelow and disposed on the first substrate and the optical die, and a plurality of second semiconductor chips disposed on the second edge region of the first substrate, wherein the electronic integrated circuit region of the first semiconductor chip is disposed on the optical die and is electrically connected to the optical die.

A semiconductor package according to some implementations of the present disclosure includes an interposer including a first edge region, a center region, and a second edge region arranged side by side in a first direction, a first semiconductor chip disposed on the interposer in the first edge region and the center region, and a plurality of second semiconductor chips disposed on the interposer in the second edge region, wherein the interposer includes a first substrate having a cavity in the first edge region, an optical die disposed in the cavity, first upper conductive pads disposed on an upper surface of the first substrate, first lower conductive pads disposed on a lower surface of the first substrate, first through vias penetrating the first substrate and connecting the first upper conductive pads and the first lower conductive pads, the optical die includes, second upper conductive pads disposed on an upper surface thereof, and a connection portion disposed on the upper surface and spaced apart from the second upper conductive pads, the first semiconductor chip includes an electronic integrated circuit region on the optical die, second lower conductive pads disposed below the electronic integrated circuit region, and third lower conductive pads disposed on the center region, each of the second semiconductor chips includes a buffer die including fourth lower conductive pads on a lower surface thereof, a plurality of memory dies sequentially stacked on the buffer die, and second through vias penetrating the buffer die and the memory dies, the second upper conductive pads of the optical die are in contact with the second lower conductive pads of the first semiconductor chip, respectively, and the second upper conductive pads of the optical die and the second lower conductive pads of the first semiconductor chip include the same material.

A semiconductor package according to some implementations of the present disclosure includes a first substrate including a first edge region, a center region, and a second edge region arranged side by side in a first direction, a chip structure disposed on the first substrate in the first edge region and the center region, and a plurality of second semiconductor chips disposed on the first substrate in the second edge region, wherein the first substrate includes a cavity formed on an upper portion of the first substrate in the first edge region and first upper conductive pads disposed on an upper surface of the first substrate, the chip structure includes a first semiconductor chip and an optical die bonded to a lower portion of the first semiconductor chip in the first edge region and inserted into the cavity, and a first level of an upper surface of the optical die is higher than a second level of an upper surface of the first substrate.

### BRIEF DESCRIPTION OF THE DRAWINGS

The foregoing and other implementations will be more clearly understood from the following description taken in conjunction with the accompanying drawings. The accompanying drawings represent non-limiting examples as described herein.

FIG. 1 is a plan view of an example of a semiconductor package.

FIG. 2 is a cross-sectional view taken along line A-A′ of FIG. 1.

FIGS. 3A to 3H are cross-sectional views sequentially showing a process of manufacturing an example of a semiconductor package of FIG. 2.

FIGS. 4A to 4F are cross-sectional views sequentially showing a process of manufacturing an example of a semiconductor package.

FIG. 5 is a cross-sectional view of an example of a semiconductor package.

FIGS. 6A to 6F are cross-sectional views sequentially showing a process of manufacturing an example of a semiconductor package.

FIG. 7 is a cross-sectional view of an example of a semiconductor package.

FIG. 8 is a cross-sectional view of an example of a semiconductor package.

FIG. 9A is a plan view of an example of a semiconductor package.

FIG. 9B is a cross-sectional view taken along line B-B′ of FIG. 9A.

FIG. 10 is a plan view of an example of a semiconductor package.

FIG. 11 is a plan view of an example of a semiconductor package.

FIG. 12 is a plan view of an example of a semiconductor package.

FIG. 13 is a cross-sectional view taken along line C-C′ of FIG. 12.

FIG. 14 is a cross-sectional view of an example of a semiconductor package.

### DETAILED DESCRIPTION

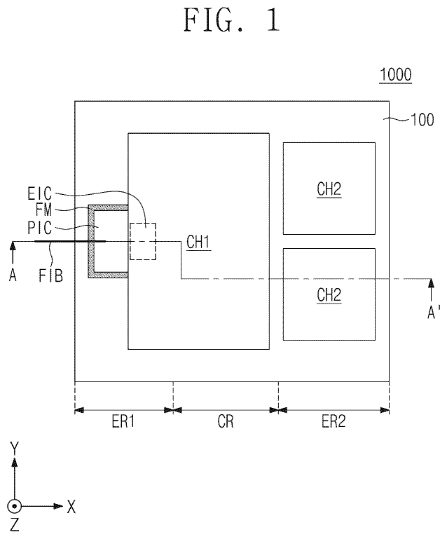

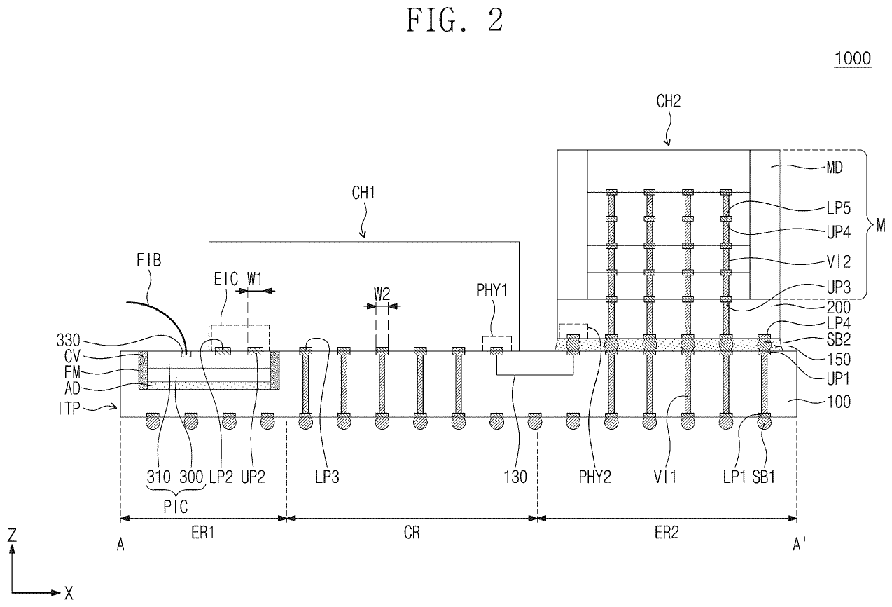

FIG. 1 is a plan view of a semiconductor package according to some implementations of the present disclosure. FIG. 2 is a cross-sectional view taken along line A-A′ of FIG. 1.

Referring to FIGS. 1 and 2, a semiconductor package 1000 includes an interposer ITP, a first semiconductor chip CH1, second semiconductor chips CH2, and an optical die PIC. The interposer ITP may include a first edge region ER1, a center region CR, and a second edge region ER2 arranged side by side in a first direction X. In the first edge region ER1, the interposer ITP may include a cavity CV formed on an upper portion thereof.

The first semiconductor chip CH1 may be disposed on the interposer ITP in the first edge region ER1 and the center region CR. The second semiconductor chip CH2 may be disposed on the interposer ITP in the second edge region ER2. A plurality of second semiconductor chips CH2 may be provided. For example, there may be two or more second semiconductor chips CH2. The optical die PIC may be disposed in the cavity CV of the interposer ITP. For example, the optical die PIC may be disposed between the interposer ITP and the first semiconductor chip CH1.

The interposer ITP may include a first substrate 100, first upper conductive pads UP1, first lower conductive pads LP1, first through vias VI1, and a connection wiring 130. The first substrate 100 may include a semiconductor material, glass, organic material, and/or another suitable substrate material. For example, the first substrate 100 may include silicon. The first substrate 100 may include the cavity CV at an upper surface of the first edge region ER1.

The first upper conductive pads UP1 may be disposed on an upper surface of the first substrate 100. The first upper conductive pads UP1 may be disposed on the center region CR and the second edge region ER2. In some implementations, the first upper conductive pads UP1 are not disposed on the first edge region ER1 and are not disposed in the cavity CV. The first lower conductive pads LP1 may be disposed on a lower surface of the first substrate 100. The first lower conductive pads LP1 may be disposed on the first edge region ER1, the center region CR, and the second edge region ER2. Each of the first upper conductive pads UP1 and the first lower conductive pads LP1 may have any of various shapes, such as square, rectangular, circular, or oval. Each of the first upper conductive pads UP1 and the first lower conductive pads LP1 may include a metal such as copper, gold, nickel, aluminum, tungsten, or titanium.

First connection members SB1 may be bonded to the first lower conductive pads LP1. The first connection members SB1 may connect a lower surface of the interposer ITP and a printed circuit substrate (not shown). The first connection members SB1 may include metal, for example, at least one of copper, nickel, tin, lead, and silver.

A plurality of first through vias VI1 may be provided through the first substrate 100. The first through vias VI1 may be disposed in the center region CR and the second edge region ER2. In some implementations, the first through vias VI1 are not disposed in the first edge region ER1. The first through vias VI1 may be arranged to be spaced apart from the cavity CV. The first through vias VI1 may be connected to corresponding first upper conductive pads UP1 and first lower conductive pads LP1, respectively. The first through vias VI1 may include metal such as copper, aluminum, or tungsten. A first through insulating layer may be interposed between the first through vias VI1 and the first substrate 100. The first through insulating layer (not shown) may have a single-layer or multi-layer structure of at least one of silicon oxide, silicon nitride, and silicon oxynitride, and may include an air gap.

Wirings may be disposed on the first substrate 100. The wirings may be formed of multi-layered wiring patterns. The wirings may be configured to transmit (e.g., carry) signals between the first and second semiconductor chips CH1 and CH2 disposed on the upper surface of the interposer ITP and a printed circuit substrate connected to the lower surface of the interposer ITP.

The first semiconductor chip CH1 may be, for example, a logic chip. The first semiconductor chip CH1 may be an application specific integrated circuit (ASIC) chip or a system on chip (SoC). The first semiconductor chip CH1 may also be referred to as a host, an application processor (AP), or the like. The first semiconductor chip CH1 may receive commands, data, signals, and the like transmitted from an external controller, and transmit the received commands, data, signals, and the like to the second semiconductor chips CH2. The first semiconductor chip CH1 may transmit data output from the second semiconductor chips CH2 to an external controller. The first semiconductor chip CH1 may include a memory controller that controls memory dies M of the second semiconductor chips CH2, which will be described later, and performs data input/output with the memory dies M.

The first semiconductor chip CH1 may include an electronic integrated circuit region EIC, second lower conductive pads LP2, third lower conductive pads LP3, a substrate, an interlayer insulating layer, a transistor, and wiring. The substrate may be, for example, a semiconductor single crystal substrate or a silicon on insulator (SOI) substrate.

The electronic integrated circuit region EIC may be disposed at a lower portion of the first semiconductor chip CH1 in the first edge region ER1. In some implementations, a plurality of electronic integrated circuit regions EIC are provided. A first physical layer region PHY1 that receives and amplifies the above-described signals may be disposed at a lower portion of the first semiconductor chip CH1 in the center region CR. The first physical layer region PHY1 may be arranged to be spaced apart from the electronic integrated circuit region EIC in the first direction X. In some implementations, a plurality of first physical layer regions PHY1 are provided. The electronic integrated circuit region EIC may operate on behalf of the first physical layer region PHY1 in the first semiconductor chip CH1.

The second lower conductive pads LP2 and third lower conductive pads LP3 may be disposed on a lower surface of the first semiconductor chip CH1. The second lower conductive pads LP2 may be disposed below the electronic integrated circuit region EIC. For example, the second lower conductive pads LP2 may be disposed on the first edge region ER1. The third lower conductive pads LP3 may be disposed on the center region CR. The second lower conductive pads LP2 may have a first width W1 of, for example, 1 μm to 7 μm. The third lower conductive pads LP3 may have a second width W2 of, for example, 1 μm to 7 μm. The first width W1 of the second lower conductive pads LP2 may be greater than or equal to the second width W2 of the third lower conductive pads LP3. In some implementations, a density (e.g., a spatial density based on a number of pads per unit area or based on an area of pads per unit area) of the second lower conductive pads LP2 disposed in the electronic integrated circuit region EIC of the first semiconductor chip CH1 is greater than a density of the third lower conductive pads LP3 disposed in the first physical layer region PHY1. Each of the second and third lower conductive pads LP2 and LP3 may have any of various shapes such as square, rectangular, circular, or oval. The second and third lower conductive pads LP2 and LP3 may each include a metal such as copper, gold, nickel, aluminum, tungsten, or titanium.

The optical die PIC may be disposed in the cavity CV of the first substrate 100 in the first edge region ER1. The semiconductor package 1000 may have a structure in which the optical die PIC is inserted into the interposer ITP. The optical die PIC may include a substrate layer 300, a device layer 310, a connection portion 330, second upper conductive pads UP2, and an optical fiber FIB. In some implementations, the optical die PIC does not include an optical fiber. The substrate layer 300 may include, for example, silicon (Si). However, the composition is not limited thereto. In some implementations, the substrate layer 300 includes an insulating oxide such as silicon oxide (SiO₂).

The device layer 310 may be disposed on the substrate layer 300. The device layer 310 may include, for example, a semiconductor device. Photonic integrated circuits (or optical integrated circuits) that play various roles may be disposed on and/or in the device layer 310. The photonic integrated circuits may include, for example, devices such as a semiconductor laser, a light source, an optical amplifier, an electric signal amplifier, an optical modulator, an optical waveguide, an optical coupler, or an optical detector. The photonic integrated circuits may serve as transceivers that receive external light into the interior of the optical die PIC or emit light from the optical die PIC to the outside. The device layer 310 may include, for example, a group III/V compound semiconductor material or a group II/VI compound semiconductor material. The device layer 310 may include an insulating material.

The connection portion 330 may be disposed on an upper surface of the device layer 310. The connection portion 330 may include an element such as a micro lens, an optical lens, or an optical waveguide. The optical fiber FIB may be connected to the connection portion 330. The optical fiber FIB may be directly connected to the connection portion 330. For example, the optical fiber FIB may be connected to the micro lens, the optical lens, or the optical waveguide to accept external light into the interior of the optical die PIC or to emit light from the optical die PIC to the outside. In some implementations, a structure serving as a connector connecting the optical fiber FIB and the connection portion 330 is disposed between the optical fiber FIB and the connection portion 330. The optical fiber FIB may connect the semiconductor package 1000 to another external semiconductor chip or semiconductor package.

The second upper conductive pads UP2 may be disposed on the device layer 310. The second upper conductive pads UP2 may be arranged to be spaced apart from the connection portion 330. A width of the second upper conductive pads UP2 may be, for example, 1 μm to 7 μm. Each of the second upper conductive pads UP2 may have any of various shapes, such as square, rectangular, circular, or oval. Each of the second upper conductive pads UP2 may include a metal such as copper, gold, nickel, aluminum, tungsten, or titanium.

The second upper conductive pads UP2 of the optical die PIC may be in direct contact with the second lower conductive pads LP2 of the first semiconductor chip CH1, respectively. The second upper conductive pads UP2 of the optical die PIC and the second lower conductive pads LP2 of the first semiconductor chip CH1 may include the same material. The second upper conductive pads UP2 of the optical die PIC and the second lower conductive pads LP2 of the first semiconductor chip CH1 that are in contact with each other may be fused with each other to form an integrated body. As the optical die PIC and the first semiconductor chip CH1 are directly connected to each other, a signal transmission distance between the photonic integrated circuits and the electronic integrated circuit region EIC may be reduced, thereby maintaining low latency when the semiconductor package 1000 operates. As a result, in some implementations, the semiconductor package 1000 with improved operation speed and optimized performance may be provided.

An adhesive member AD may be interposed between a bottom surface of the cavity CV of the first substrate 100 and a bottom surface of the optical die PIC. The adhesive member AD may include, for example, die attach film (DAF) or epoxy resin.

A filling member FM may be interposed between the optical die PIC and an inner wall of the cavity CV. The filling member FM may fill a space between the adhesive member AD and the inner wall of the cavity CV. An upper surface of the filling member FM may be coplanar with an upper surface of the optical die PIC. The upper surface of the filling member FM may be coplanar with an upper surface of the interposer ITP. The filling member FM may include, for example, an insulating resin such as epoxy-based molding compound (EMC). However, the filling member FM is not limited thereto.

Each of the second semiconductor chips CH2 may have, for example, a high bandwidth memory (HBM) chip structure. Each of the second semiconductor chips CH2 may include a buffer die 200, a plurality of memory dies M, and a mold layer MD. A plurality of memory dies M may be stacked on the buffer die 200. The buffer die 200 may be a base die including a semiconductor device. In some implementations, the buffer die 200 is an interface die, logic die, master die, or the like. A die may also be referred to as a chip. The buffer die 200 may operate as an interface circuit between the memory dies M and an external controller. Each of the memory dies M may be a flash memory chip, DRAM chip, SRAM chip, EEPROM chip, PRAM chip, MRAM chip, or ReRAM chip.

The buffer die 200 and the memory dies M may each include a substrate, an interlayer insulating layer, second through vias VI2, a transistor, and wires. The substrate may be, for example, a semiconductor single crystal substrate or a silicon on insulator (SOI) substrate. The second through vias VI2 may penetrate the substrate of the buffer die 200 and the memory dies M, respectively, to electrically connect the buffer die 200 and the memory dies M. An uppermost memory die M may not include the second through vias VI2. The second through vias VI2 may include metal such as copper, aluminum, or tungsten.

Third upper conductive pads UP3 may be disposed on an upper surface of the buffer die 200 and fourth lower conductive pads LP4 may be disposed on a lower surface thereof. Fourth upper conductive pads UP4 may be disposed on the upper surface of each of the memory dies M, respectively, and fifth lower conductive pads LP5 may be disposed on the lower surface thereof, respectively. The uppermost memory die M may not include the fourth upper conductive pads UP4. Each of the third and fourth upper conductive pads UP3 and UP4 and the fourth and fifth lower conductive pads LP4 and LP5 may be connected to corresponding second through vias VI2. Each of the third and fourth upper conductive pads UP3 and UP4 and the fourth and fifth lower conductive pads LP4 and LP5 may include a metal such as copper, gold, nickel, aluminum, tungsten, or titanium.

The mold layer MD may cover the buffer die 200 and the memory dies M. For example, the mold layer MD may include an insulating resin such as epoxy-based molding compound (EMC). The mold layer MD may further include a filler, and the filler may be dispersed in the insulating resin. The filler may include, for example, silicon oxide (SiO₂).

Second connection members SB2 may be disposed to connect an upper surface of the first substrate 100 and lower surfaces of the second semiconductor chips CH2, respectively. The second connection members SB2 may be connected to the corresponding first upper conductive pads UP1 of the first substrate 100 and fourth lower conductive pads LP4 of the buffer die 200, respectively. The second semiconductor chips CH2 may be mounted on the first substrate 100 through the second connection members SB2 in a flip-chip bonding arrangement. The second connection members SB2 may include, for example, at least one of a copper bump, a copper pillar, and a solder ball.

An underfill 150 may be interposed between the upper surface of the first substrate 100 and the lower surface of the second semiconductor chips CH2. The underfill 150 may include, for example, epoxy resin, and may protect the second connection members SB2.

The buffer die 200 may include a second physical layer region PHY2, buffering circuits, or interface circuits that receive and amplify the above-described signals. The second physical layer region PHY2 may be disposed at a lower portion of the buffer die 200 and may be provided in a plurality. The first substrate 100 of the interposer ITP may include the connection wiring 130 connecting the first physical layer region PHY1 of the first semiconductor chip CH1 to the second physical layer region PHY2 of the second semiconductor chip CH2. The first semiconductor chip CH1 and the second semiconductor chip CH2 may be electrically connected through the connection wiring 130. The connection wiring 130 may include, for example, one of copper (Cu), aluminum (Al), silver (Ag), tin (Sn), gold (Au), nickel (Ni), lead (Pb), or titanium (Ti).

The semiconductor package 1000 may receive an external optical signal into the interior of the optical die PIC through the optical fiber FIB and convert the external optical signal into an electrical signal through the electronic integrated circuit region EIC of the first semiconductor chip CH1. The converted electrical signal may be transmitted from the first physical layer region PHY1 of the first semiconductor chip CH1 to the second physical layer region PHY2 of the buffer die 200 through the connection wiring 130 of the interposer ITP, thereby being transmitted to the memory dies M. In addition, data output from the memory dies M may be transmitted from the second physical layer region PHY2 of the buffer die 200 to the first physical layer region PHY1 of the first semiconductor chip CH1 through the connection wiring 130 of the interposer ITP. Afterwards, the signal may be transmitted from the electronic integrated circuit region EIC of the first semiconductor chip CH1 to the optical die PIC, may be converted into an optical signal in the optical die PIC, and then may be transmitted to the outside through the optical fiber FIB.

As discussed above, in some implementations, a structure in which the optical die PIC and the electronic integrated circuit region EIC of the first semiconductor chip CH1 are directly connected may be provided, and thus the signal transmission distance between the optical die PIC and the electronic integrated circuit region EIC of the first semiconductor chip CH1 may be reduced, thereby improving operation speed of the semiconductor package 1000. In addition, in some implementations, the electronic integrated circuit region EIC may be disposed inside the first semiconductor chip CH1, and the optical die PIC may be bonded to the lower portion of the first semiconductor chip CH1, thereby reducing the area of the interposer ITP or the area of the package substrate on which the first and second semiconductor chips CH1 and CH2 are mounted, and optically connecting the semiconductor packages 1000. As a result, a semiconductor package 1000 with improved operation speed and optimized performance may be provided.

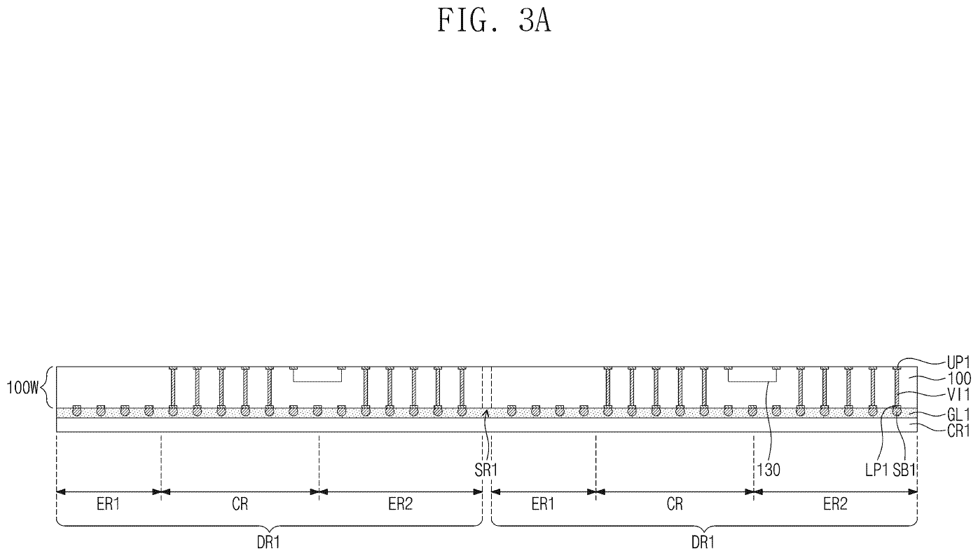

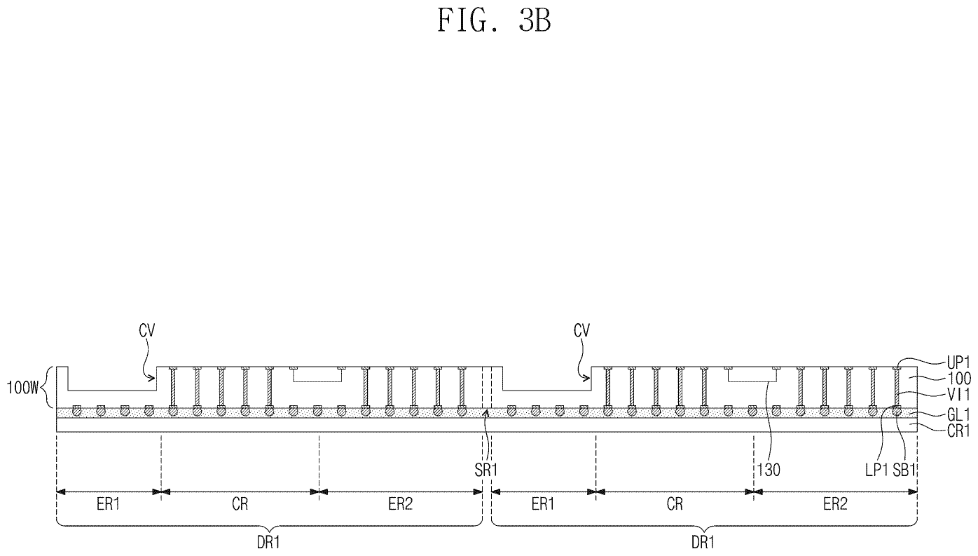

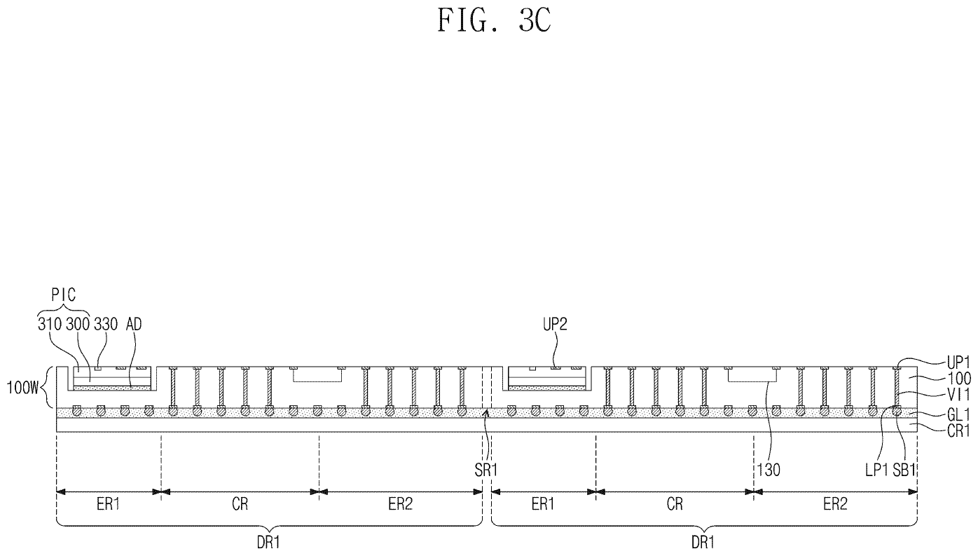

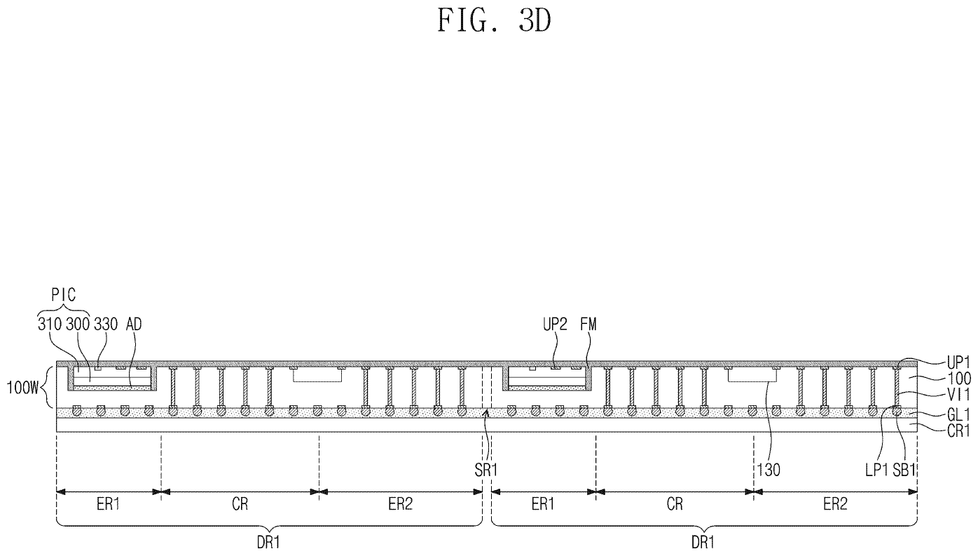

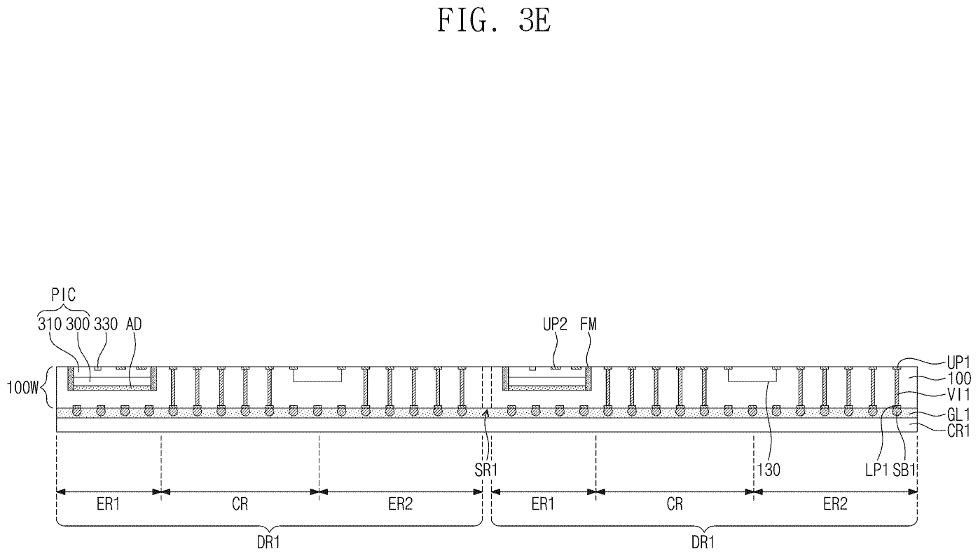

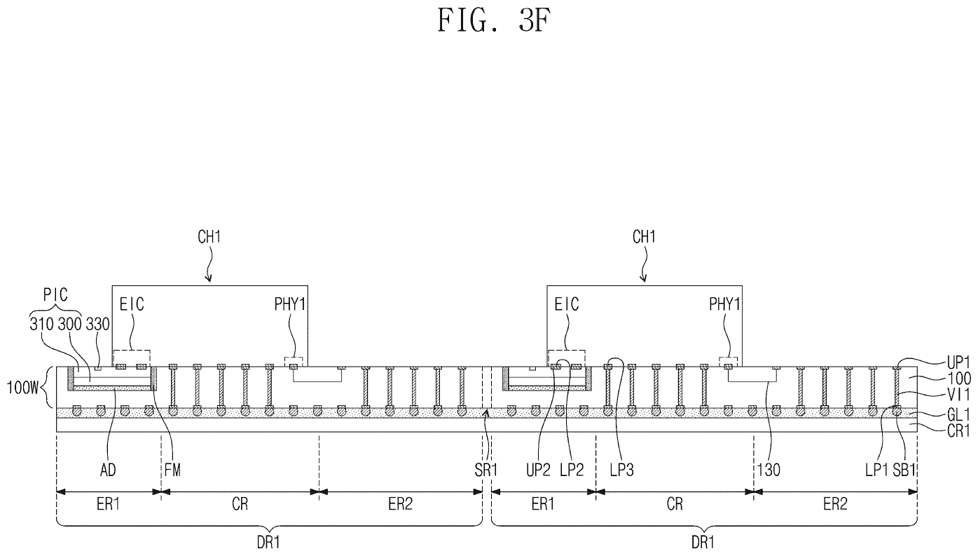

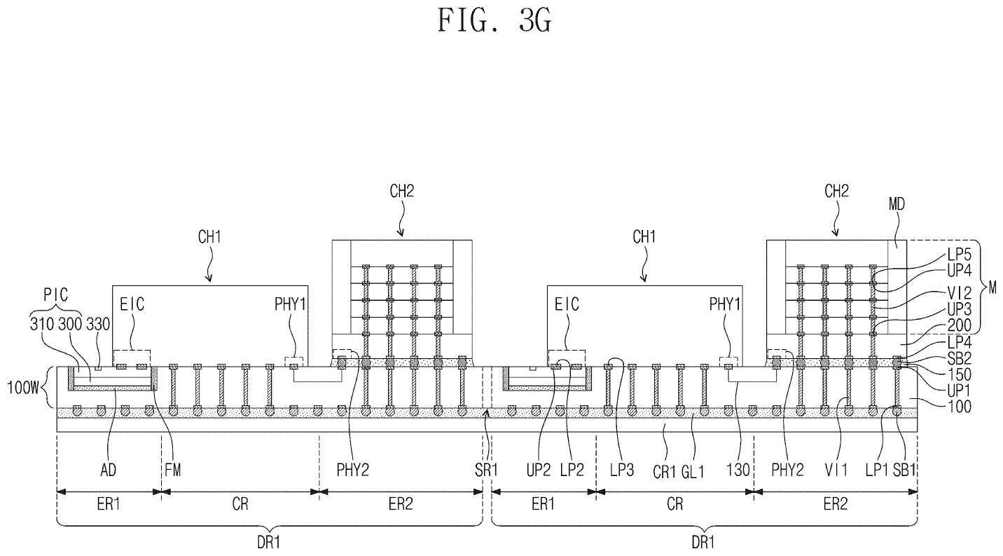

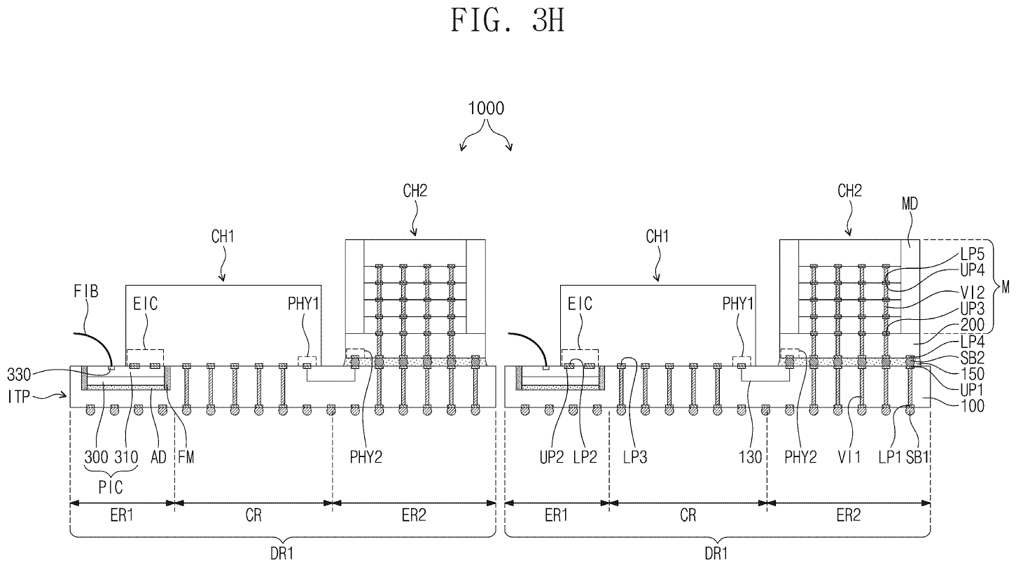

FIGS. 3A to 3H are cross-sectional views sequentially showing a process of manufacturing the semiconductor package of FIG. 2, according to some implementations of the present disclosure. Hereinafter, content that overlaps with what was previously described will be omitted.

Referring to FIG. 3A, a wafer 100W for a first substrate is prepared. The first substrate wafer 100W may have a plurality of first chip regions DR1 and a first separation region SR1 therebetween. The first chip regions DR1 of the first substrate wafer 100W may have the structure of the interposer ITP described with reference to FIGS. 1 and 2, respectively. The first separation region SR1 may be a scribe lane region. The first substrate wafer 100W may include the first substrate 100. Each of the first chip regions DR1 of the first substrate wafer 100W may include a first edge region ER1, a center region CR, and a second edge region ER2.

Through a conventional process, first through vias VI1, first upper conductive pads UP1, first lower conductive pads LP1, a connection wiring 130, and first connection members SB1 may be formed on the first chip regions DR1 of the first substrate wafer 100W. The first upper conductive pads UP1 may be formed on the center region CR and the second edge region ER2. The first substrate wafer 100W may be bonded to a first carrier substrate CR1 through a first carrier adhesive layer GL1 so that the first connection members SB1 face downward. The first carrier substrate CR1 may be an insulating substrate containing glass or polymer, or a conductive substrate containing metal. The first carrier adhesive layer GL1 may include an adhesive/thermosetting/thermoplastic/photocurable resin.

Referring to FIG. 3B, cavities CV may be formed in an upper portion of the first substrate wafer 100W on the first edge regions ER1 by performing an etching process. Bottom surfaces of the cavities CV may be positioned at a vertical level higher than a bottom surface of the first substrate 100.

FIGS. 3C to 3G illustrate a manufacturing process in which an optical die PIC and first and second semiconductor chips CH1 and CH2 are mounted on the first substrate wafer 100W using a die to wafer approach. Referring to FIG. 3C, optical dies PIC are prepared. A substrate layer 300 and a device layer 310 on the substrate layer 300 may be formed in a wafer form through a conventional process. Connection portions 330 and second upper conductive pads UP2 may be formed on the device layer 310. After forming an adhesive member AD on the lower portion of the substrate layer 300, a plurality of optical dies PIC may be formed through a sawing process. Thereafter, as shown in FIG. 3C, each optical die PIC may be bonded to a bottom surface of the cavity CV.

Referring to FIG. 3D, a mold process may be performed to form a filling member FM that fills a space between the optical die PIC and an inner surface of the cavity CV and covers upper surfaces of the optical dies PIC and an upper surface of the first substrate wafer 100W.

Referring to FIG. 3E, a chemical mechanical polishing (CMP) or etch-back process may be performed to remove at least a portion of the filling member FM, thereby exposing upper surfaces of the first substrate 100, the first upper conductive pads UP1, the second upper conductive pads UP2, the device layer 310, the connection portion 330, and the filling member FM. In this process, at least a portion of an upper surface of the optical die PIC and an upper surface of the first substrate wafer 100W may be removed.

Referring to FIG. 3F, first semiconductor chips CH1 are prepared. Through a conventional process, a substrate, a transistor, wiring, an interlayer insulating layer, an electronic integrated circuit EIC, a second lower conductive pads LP2, and third lower conductive pads LP3 may be formed. The first semiconductor chips CH1 may be bonded on the first substrate wafer 100W through a thermal compression process. For example, a direct bonding process or hybrid copper (Cu) bonding may be performed. The first semiconductor chips CH1 are disposed on the center region CR and the first edge region ER1 of the first substrate wafer 100W. After the second lower conductive pads LP2 of the first semiconductor chip CH1 are in contact with the second upper conductive pads UP2 of the optical die PIC, and the third lower conductive pads LP3 of the first semiconductor chip CH1 are in contact with the first upper conductive pads UP1 of the first substrate wafer 100W, the first semiconductor chips CH1 may be directly bonded to the first substrate wafer 100W by performing a thermal compression process.

Referring to FIG. 3G, second semiconductor chips CH2 may be prepared. Through a conventional process, a substrate, an interlayer insulating layer, second through vias VI2, a transistor, and wiring may be formed on each of the buffer die 200 and the memory dies M. After stacking the memory dies M on the buffer die 200, the memory dies M may be bonded to the buffer die 200 through a thermocompression process, and a mold layer covering them may be formed. A dicing process may be performed to form a plurality of second semiconductor chips CH2. The second semiconductor chips CH2 may be bonded to the first substrate wafer 100W using a flip-chip bonding manner. The second semiconductor chips CH2 are disposed on the second edge region ER2 of the first substrate wafer 100W. For example, the second semiconductor chips CH2 may be positioned so that the second connection members SB2 overlap the first upper conductive pads UP1 in the second edge region ER2. A thermocompression process may be performed to bond the second semiconductor chips CH2 to the first substrate wafer 100W. An underfill 150 may be formed through a dispensing and curing process to fill spaces between the first substrate wafer 100W and the second semiconductor chips CH2.

Referring to FIG. 3H, after the first substrate wafer 100W is separated from the first carrier adhesive layer GL1, a dicing process may be performed to remove the first separation region SR1. Thereafter, optical fibers FIB may be connected to the connection portions 330 to form a plurality of semiconductor packages 1000. Accordingly, the semiconductor packages 1000 of FIG. 2 may be formed.

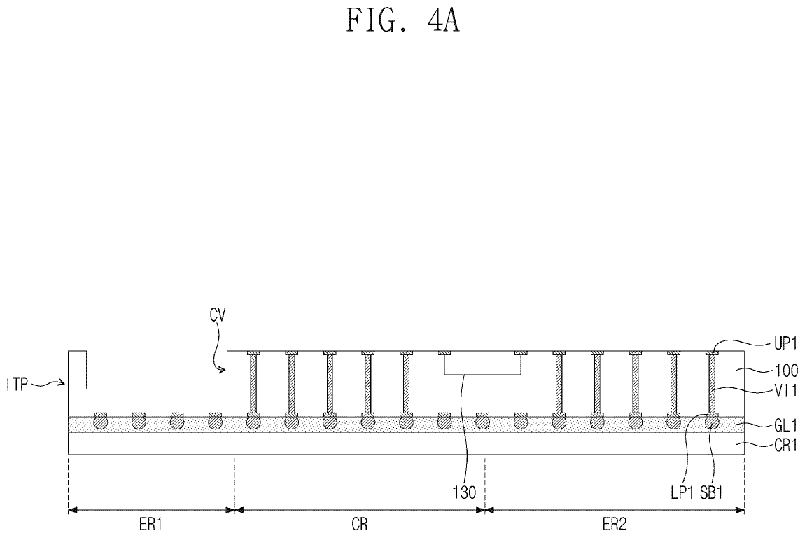

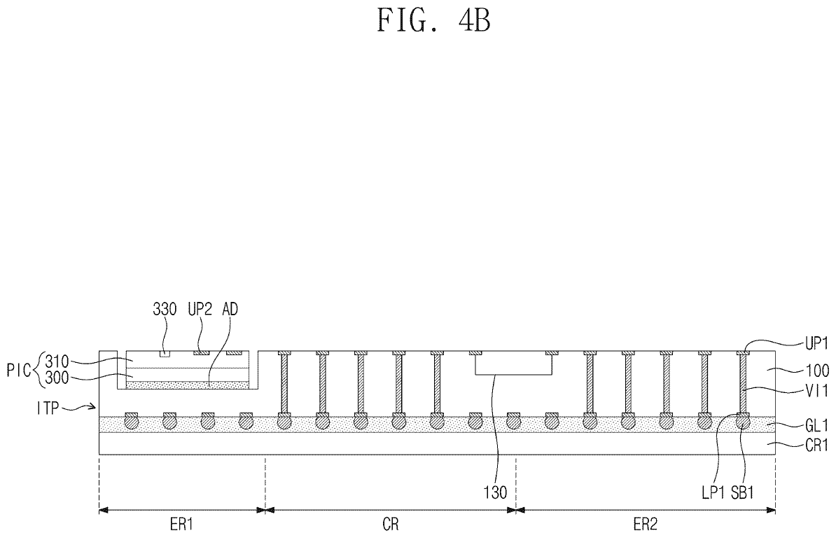

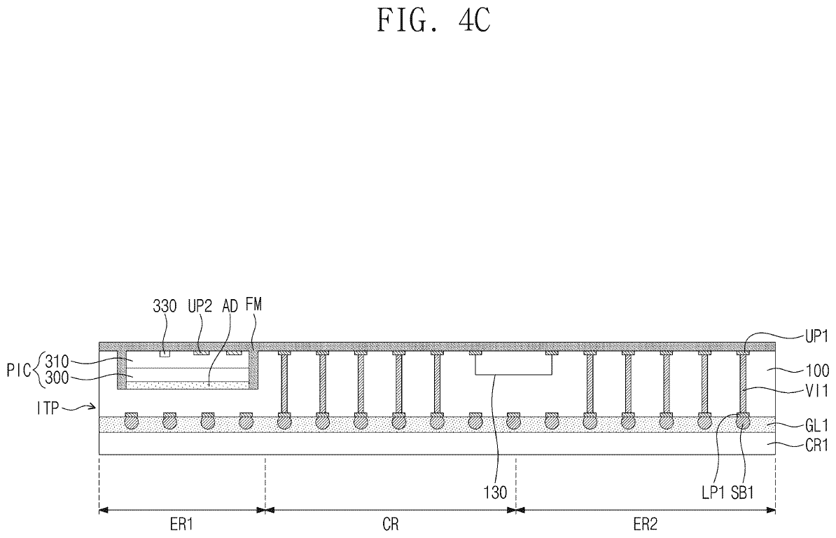

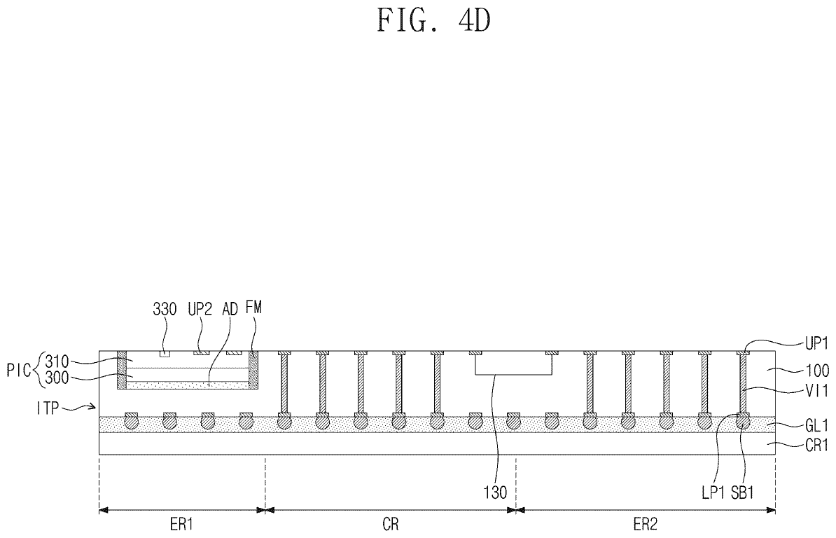

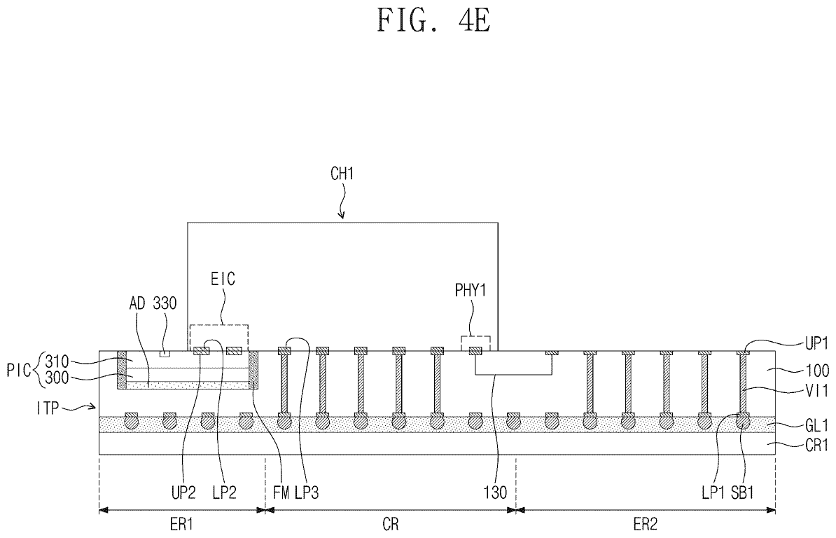

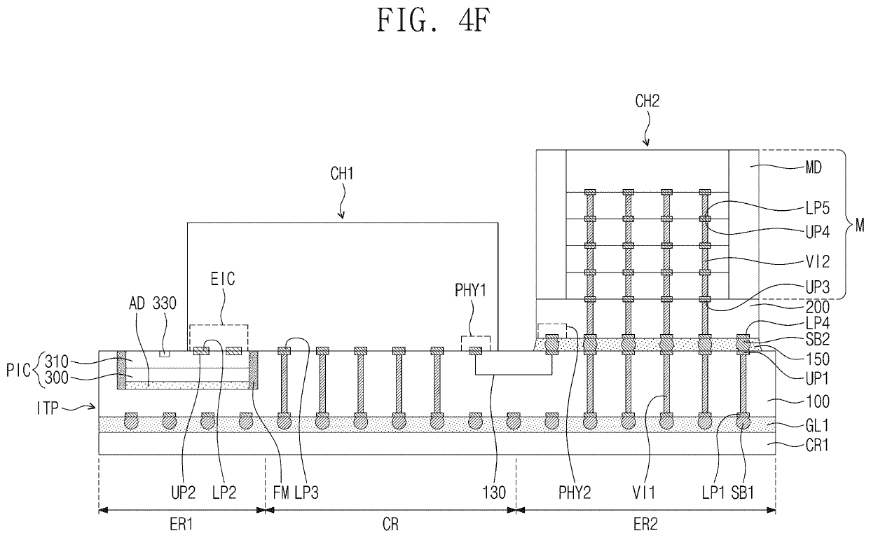

The semiconductor package of FIG. 2 may be manufactured using a die to die manner as shown in FIGS. 4A to 4F, e.g., rather than the die to wafer method of FIGS. 3A to 3H. For example, FIGS. 4A to 4F are cross-sectional views sequentially showing a process of manufacturing the semiconductor package of FIG. 2 according to some implementations of the present disclosure.

Hereinafter, content that overlaps with what was previously described will be omitted. Referring to FIG. 4A, an interposer ITP is prepared. The interposer ITP may have the structure of the interposer ITP described with reference to FIGS. 1 and 2 and may include a first substrate 100. The interposer ITP may be formed using the same or similar manufacturing methods as described with reference to FIGS. 3A and 3B. The interposer ITP may be formed by removing the first separation region SR1 of FIG. 3B through a sawing process. The interposer ITP may have a first edge region ER1, a center region CR, and a second edge region ER2.

FIGS. 4B to 4F illustrate a manufacturing process in which the optical die PIC and first and second semiconductor chips CH1 and CH2 are mounted on the interposer ITP using a die to die manner. Referring to FIG. 4B, an optical die PIC is prepared. The optical die PIC may be formed using the same or similar manufacturing methods as described with reference to FIG. 3C, and the optical die PIC may be bonded to a bottom surface of the cavity CV.

Referring to FIG. 4C, a dispensing or molding process may be performed to form a filling member FM that fills a space between the optical die PIC and an inner surface of the cavity CV, and covers an upper surface of the optical die PIC and an upper surface of the first substrate 100.

Referring to FIG. 4D, a chemical mechanical polishing (CMP) or etch-back process may be performed to remove at least a portion of the filling member FM, thereby exposing upper surfaces of the first substrate 100, the first upper conductive pads UP1, and the second upper conductive pads UP2, the device layer 310, the connection portion 330, and the filling member FM. In this process, at least a portion of an upper surface of the optical die PIC and an upper surface of the first substrate 100 may be removed.

Referring to FIG. 4E, a first semiconductor chip CH1 is prepared. The first semiconductor chip CH1 may be formed using the same or similar manufacturing methods as described with reference to FIG. 3F, and the first semiconductor chips CH1 may be bonded to the first substrate 100 through a thermal compression process. For example, a direct bonding process or hybrid copper (Cu) bonding may be performed. The first semiconductor chip CH1 is disposed on the center region CR and the first edge region ER1 of the first substrate 100. After the second lower conductive pads LP2 of the first semiconductor chip CH1 are in contact with the second upper conductive pads UP2 of the optical die PIC, and the third lower conductive pads LP3 of the first semiconductor chip CH1 are in contact with the first upper conductive pads UP1 of the first substrate 100, the first semiconductor chip CH1 may be directly bonded to the first substrate 100 by performing a thermal compression process.

Referring to FIG. 4F, second semiconductor chips CH2 are prepared. The second semiconductor chips CH2 may be formed using the same or similar manufacturing methods as described with reference to FIG. 3G, and the second semiconductor chips CH2 may be bonded to the first substrate 100 using flip-chip bonding manner. The second semiconductor chips CH2 are disposed on the second edge region ER2 of the first substrate 100. For example, the second semiconductor chips CH2 may be positioned so that the second connection members SB2 overlap the first upper conductive pads UP1 on the second edge region ER2. A thermal compression process is performed to bond the second semiconductor chips CH2 to the first substrate 100. An underfill 150 may be formed through a dispensing and curing process to fill spaces between the first substrate 100 and the second semiconductor chips CH2. Thereafter, an optical fiber FIB may be connected to a connection portion 330, thereby forming the semiconductor package 1000 of FIG. 2.

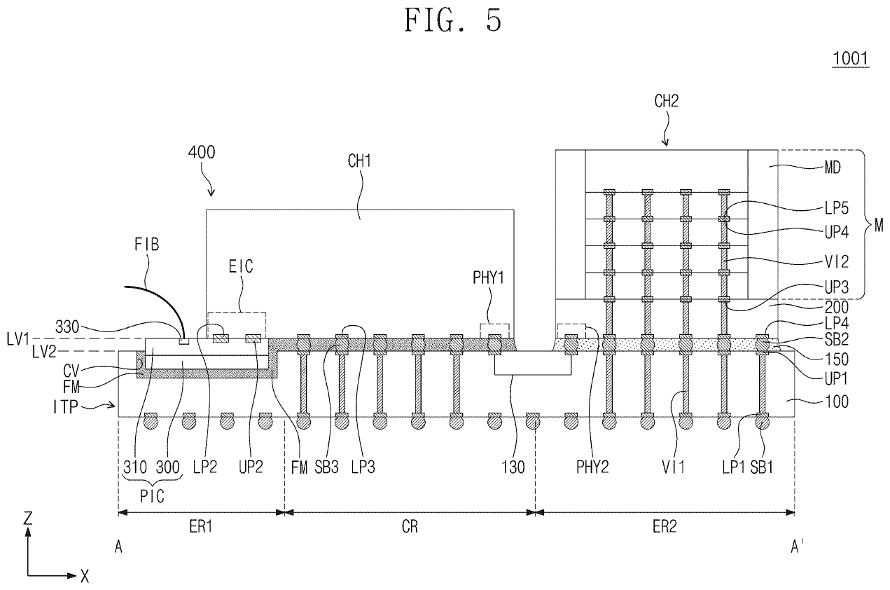

FIG. 5 is a cross-sectional view of a semiconductor package according to some implementations of the present disclosure.

Referring to FIG. 5, a semiconductor package 1001 may include an interposer ITP, a chip structure 400, and a second semiconductor chip CH2. The interposer ITP may include a first edge region ER1, a center region CR, and a second edge region ER2 arranged in a first direction X. The chip structure 400 may include a first semiconductor chip CH1 and an optical die PIC. The semiconductor package 1001 may have the overall structure of FIG. 2 in which the first semiconductor chip CH1 is bonded to the interposer ITP using a flip chip bonding manner.

Third connection members SB3 may be disposed to connect an upper surface of the first substrate 100 and the first semiconductor chip CH1. The third connection members SB3 may be connected to the corresponding first upper conductive pads UP1 of the first substrate 100 and third lower conductive pads LP3 of the first semiconductor chip CH1, respectively. The third connection members SB3 may include, for example, at least one of a copper bump, a copper pillar, and a solder ball.

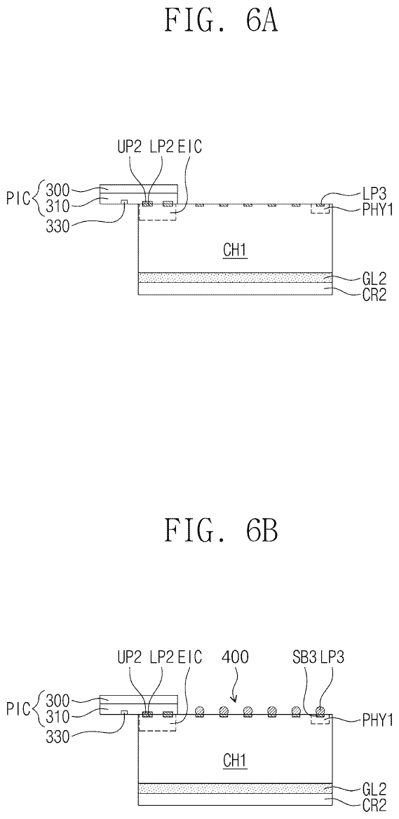

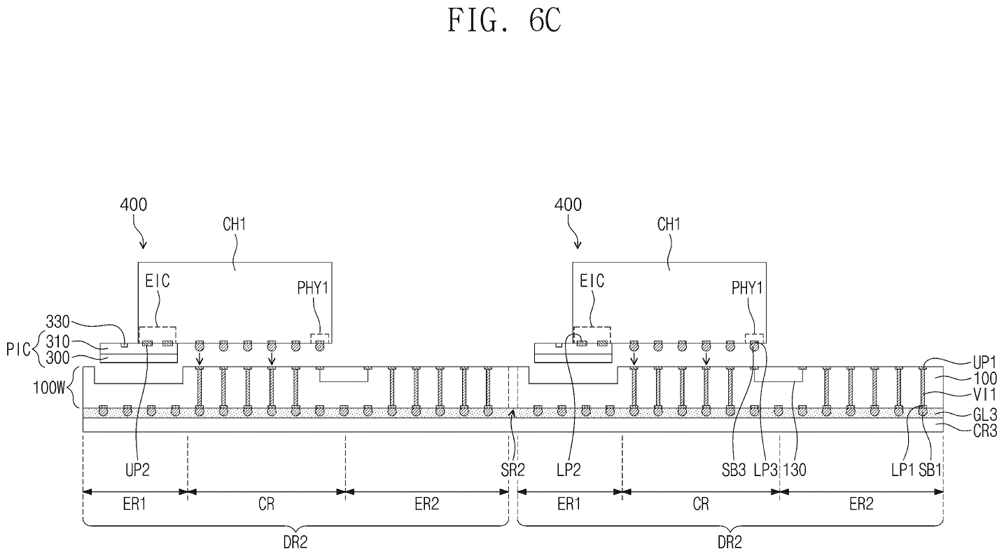

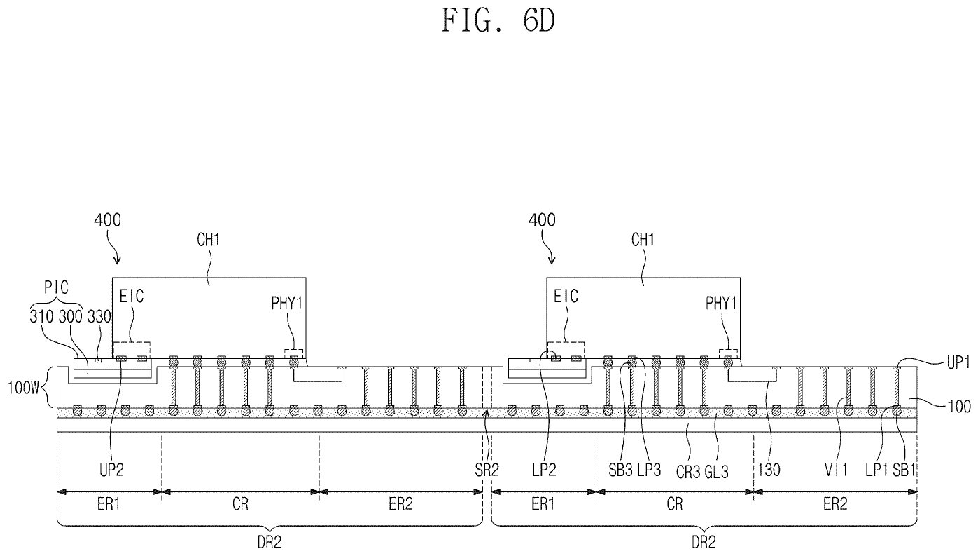

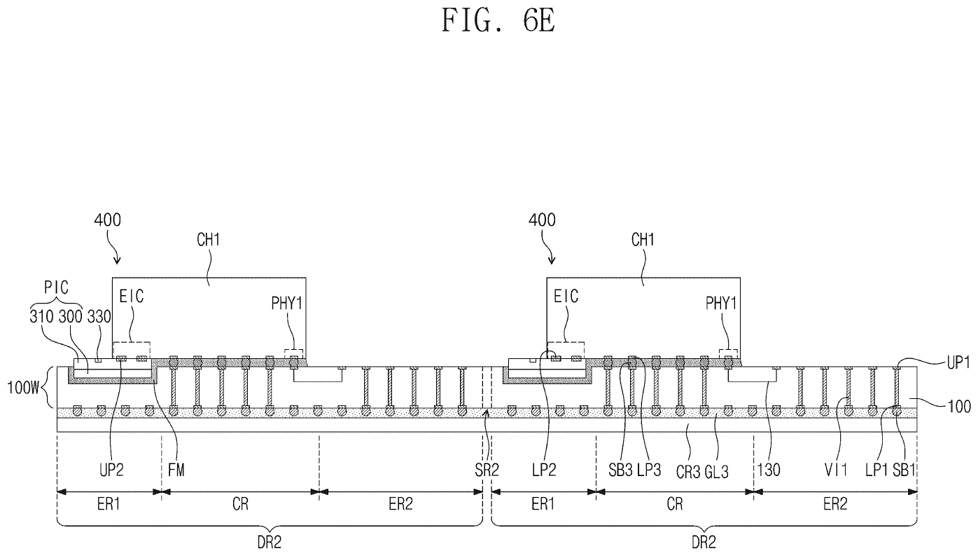

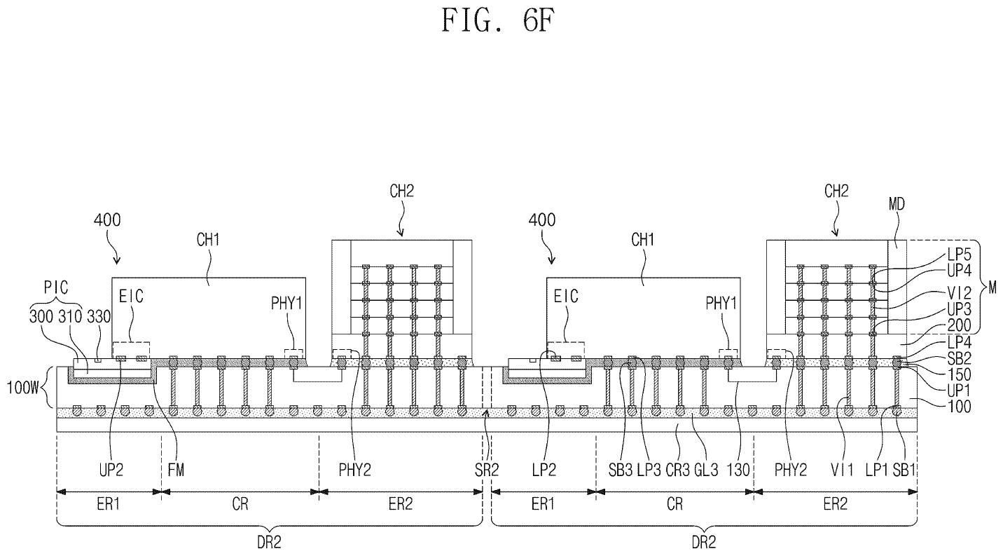

The optical die PIC may be bonded to a bottom of the first semiconductor chip CH1 in the first edge region ER1. The optical die PIC may be inserted into the cavity CV of the interposer ITP. A filling member FM may be interposed between the optical die PIC and an inner wall of the cavity CV, between the optical die PIC and a bottom surface of the cavity CV, and between the first semiconductor chip CH1 and the first substrate 100. The filling member FM may include, for example, an insulating resin such as epoxy-based molding compound (EMC). A first level LV1 of the upper surface of the optical die PIC may be higher than a second level LV2 of the upper surface of the first substrate 100. Other aspects of the semiconductor package 1001 may be the same as or similar to those of the semiconductor package 1000 described with reference to FIGS. 1 and 2. FIGS. 6A to 6F are cross-sectional views sequentially showing a process of manufacturing the semiconductor package of FIG. 5 according to some implementations of the present disclosure. Hereinafter, content that overlaps with what was previously described will be omitted.

Referring to FIG. 6A, a first semiconductor chip CH1 and an optical die PIC are prepared. The first semiconductor chip CH1 and the optical die PIC may be formed using the same or similar manufacturing methods as described with reference to FIGS. 3C and 3F. The first semiconductor chip CH1 may be bonded to a second carrier substrate CR2 through a second carrier adhesive layer GL2 so that an upper surface of the first semiconductor chip CH1 faces downward. The second carrier substrate CR2 may be an insulating substrate containing glass or polymer, or a conductive substrate containing metal. The second carrier adhesive layer GL2 may include an adhesive/thermosetting/thermoplastic/photocurable resin.

The optical die PIC is disposed on the first semiconductor chip CH1 so that the device layer 310 of the optical die PIC faces downward. After placing the second lower conductive pads LP2 of the first semiconductor chip CH1 in contact with the second upper conductive pads UP2 of the optical die PIC, the optical die PIC may be bonded directly onto the first semiconductor chip CH1 by performing a thermocompression process. For example, a direct bonding process or hybrid copper (Cu) bonding may be performed.

Referring to FIG. 6B, third connection members SB3 may be bonded to the third lower conductive pads LP3 of the first semiconductor chip CH1. Thereafter, the first semiconductor chip CH1 is separated from the second carrier adhesive layer GL2. Accordingly, the chip structure 400 of FIG. 5 may be formed.

Referring to FIG. 6C, a wafer 100W for a first substrate is prepared. The first substrate wafer 100W may have a plurality of second chip regions DR2 and a second separation region SR2 therebetween. The second chip regions DR2 of the first substrate wafer 100W may have the structure of the interposer ITP described with reference to FIGS. 1 and 2, respectively. The second separation region SR2 may be a scribe lane region. The first substrate wafer 100W may include the first substrate 100. The first substrate wafer 100W may include a first edge region ER1, a center region CR, and a second edge region ER2. The first substrate wafer 100W may be formed using the same or similar manufacturing methods as described with respect to FIGS. 3A and 3B.

The first substrate wafer 100W may be bonded to the third carrier substrate CR3 through a third carrier adhesive layer GL3 so that the first connection members SB1 face downward. The third carrier substrate CR3 may be an insulating substrate containing glass or polymer, or a conductive substrate containing metal. The third carrier adhesive layer GL3 may include an adhesive/thermosetting/thermoplastic/photocurable resin. The chip structures 400 are disposed on the first edge region and the center region CR of the first substrate wafer 100W.

Referring to FIG. 6D, the chip structures 400 may be bonded to the first substrate 100 in a flip-chip bonding arrangement. For example, the chip structures 400 may be disposed such that the optical die PIC is inserted into the cavity CV of the first substrate 100 and the third connection members SB3 overlap the first upper conductive pads UP1 on the center region CR. A thermal compression process is performed to bond the chip structures 400 to the first substrate 100.

Referring to FIG. 6E, a filling member FM may be formed through a dispensing process to fill spaces between the optical die PIC and an inner wall of the cavity CV, between the optical die PIC and a bottom surface of the cavity CV, and between the first semiconductor chip CH1 and the first substrate 100.

Referring to FIG. 6F, the second semiconductor chips CH2 may be bonded to the first substrate 100 in a flip-chip bonding arrangement. The second semiconductor chips CH2 may be bonded to the first substrate 100 using the same or similar manufacturing methods as described with reference to FIG. 3G. Afterwards, the second separation region SR2 may be removed through a dicing process and optical fibers FIB may be connected to the connection portions 330, thereby forming the semiconductor package 1001 of FIG. 5.

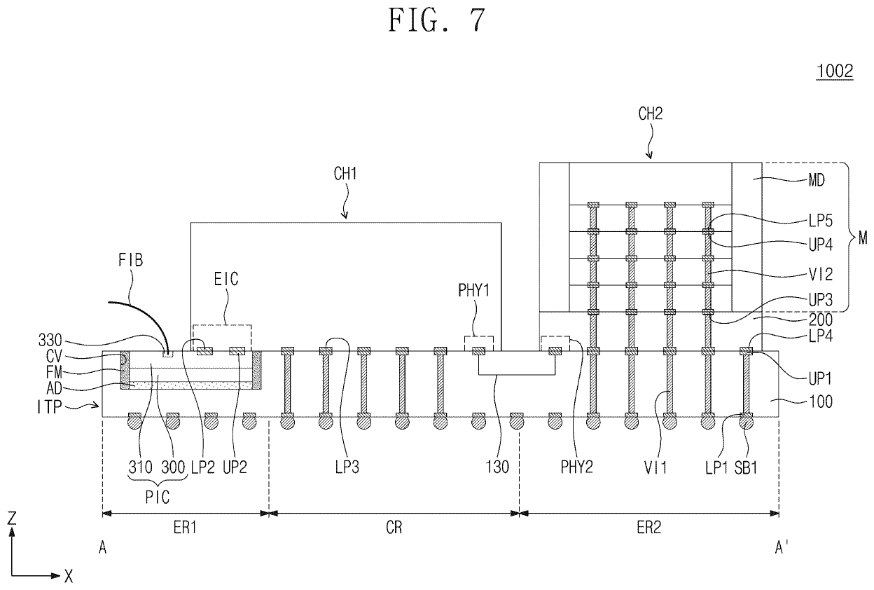

FIG. 7 is a cross-sectional view of a semiconductor package according to some implementations of the present disclosure.

Referring to FIG. 7, a semiconductor package 1002 has a structure in which the second semiconductor chips CH2 are directly bonded to the interposer ITP or hybrid copper bonded thereto. Other aspects of the semiconductor package 1002 may be the same as or similar to those described for the semiconductor package 1000 of FIG. 2. The first upper conductive pads UP1 of the first substrate 100 may be in direct contact with the corresponding fourth lower conductive pads LP4 of the second semiconductor chip CH2. The first upper conductive pads UP1 of the first substrate 100 and the corresponding fourth lower conductive pads LP4 of the second semiconductor chip CH2 may include the same material. The first upper conductive pad UP1 of the first substrate 100 and the fourth lower conductive pad LP4 of the second semiconductor chip CH2 that are in contact with each other may be fused to form an integrated body. The second semiconductor chips CH2 may be directly bonded to the interposer ITP, thereby improving signal transmission speed.

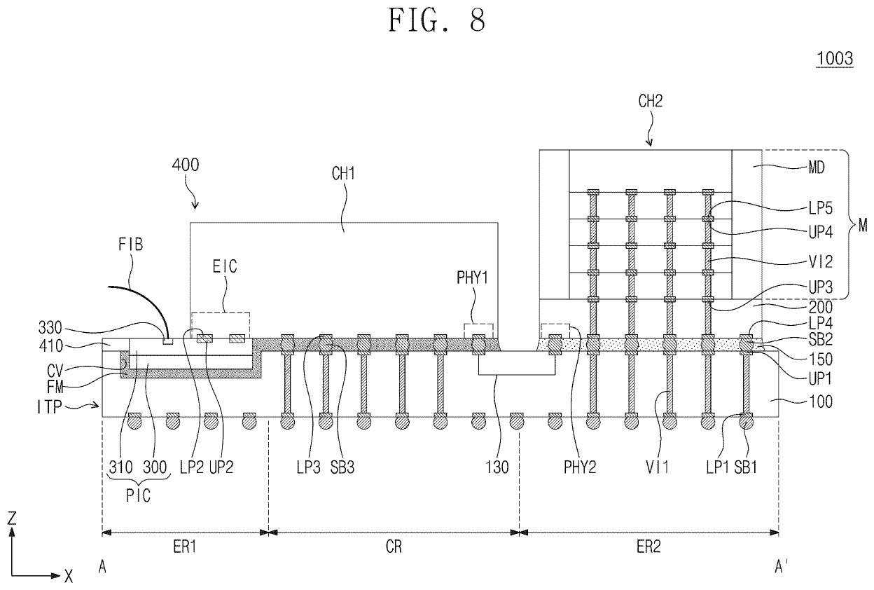

FIG. 8 is a cross-sectional view of a semiconductor package according to some implementations of the present disclosure.

Referring to FIG. 8, a semiconductor package 1003 includes a support structure 410. A level of the upper surface of the support structure 410 may be the same as a level of the upper surface of the optical die PIC. The support structure 410 may protect an exposed side of the optical die PIC from external impact and may prevent cracks or separation between the optical die PIC and the filling member FM. Support structure 410 may include silicone, for example. However, the material(s) are not limited thereto. Other aspects of the semiconductor package 1003 may be the same as or similar to those described with reference to the semiconductor packages 1000 and 1001 of FIGS. 1, 2, and 5.

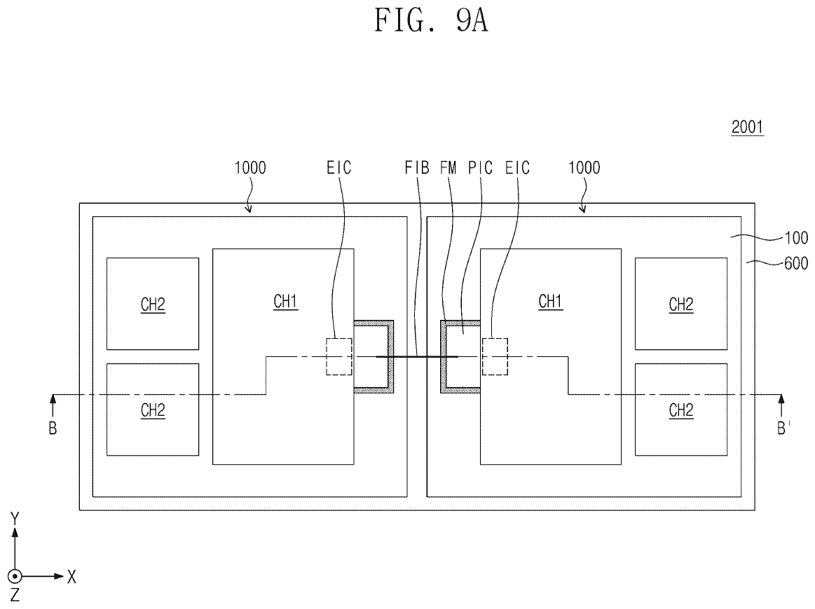

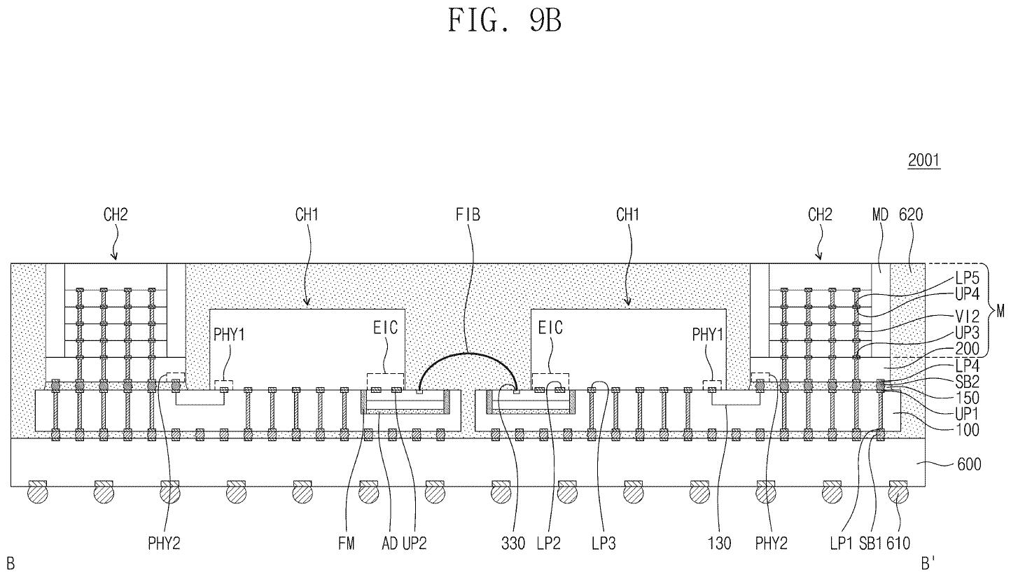

FIG. 9A is a plan view of a semiconductor package according to some implementations of the present disclosure. FIG. 9B is a cross-sectional view taken along line B-B′ of FIG. 9A.

Referring to FIGS. 9A and 9B, a semiconductor package 2001 includes a package substrate 600. The package substrate 600 may be, for example, a double-sided or multi-layer printed circuit substrate. External connection members 610 may be bonded to a lower portion of the package substrate 600. The external connection members 610 may include metal, for example, at least one of copper, nickel, tin, lead, and silver. Semiconductor packages 1000 (having the characteristics described above) may be disposed on the package substrate 600. The semiconductor package 2001 may have a structure in which two semiconductor packages 1000 are connected while facing each other in the first direction X. The semiconductor packages 1000 may be connected to each other through an optical fiber FIB. As a result, the semiconductor package 2001 may have an interconnect structure.

A package mold layer 620 may cover the package substrate 600, the first substrate 100, the first semiconductor chips CH1, the second semiconductor chips CH2, and the optical fiber FIB. The package mold layer 620 may include an insulating resin such as, for example, epoxy-based molding compound (EMC). The semiconductor packages 1000 may be the same/similar to the semiconductor packages 1000 described with reference to FIGS. 1 and 2. In some implementations, in place of one or both of the semiconductor packages 1000 shown in FIGS. 9A-9B, the semiconductor package 2001 includes one or more of the semiconductor packages 1001, 1002, and/or 1003 described with reference to FIGS. 5 to 8. Other aspects of the semiconductor package 2001 may be the same as or similar to those described with reference to FIGS. 1 to 8.

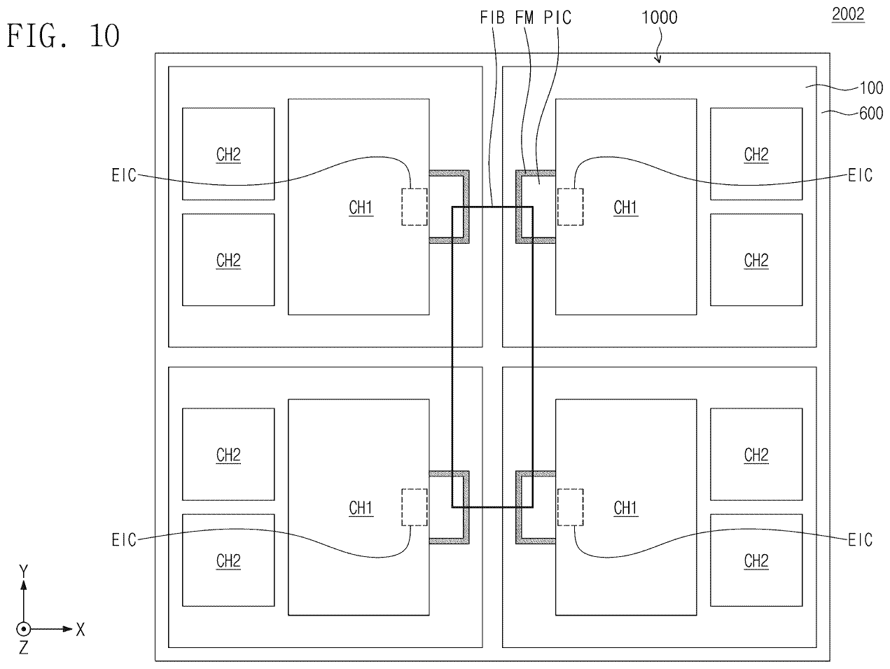

FIG. 10 is a plan view of a semiconductor package according to some implementations of the present disclosure.

Referring to FIG. 10, a semiconductor package 2002 includes a package substrate 600. The package substrate 600 may be, for example, a double-sided or multi-layer printed circuit substrate. Semiconductor packages 1000 may be disposed on the package substrate 600. The semiconductor package 2002 may have a structure in which four semiconductor packages 1000 are connected to each other in the first direction X and a second direction Y. The semiconductor packages 1000 may be the same as or similar to the semiconductor packages 1000 described with reference to FIGS. 1 and 2. In some implementations, in place of one or more of the semiconductor packages 1000 shown in FIG. 10, the semiconductor package 2002 includes one or more of the semiconductor packages 1001, 1002, and/or 1003 described with reference to FIGS. 5 to 8. The semiconductor packages 1000 may be connected to each other through an optical fiber FIB. As a result, the semiconductor package 2002 may have an interconnect structure. Other aspects of the semiconductor package 2002 may be the same as or similar to those described with reference to FIGS. 1 to 9B.

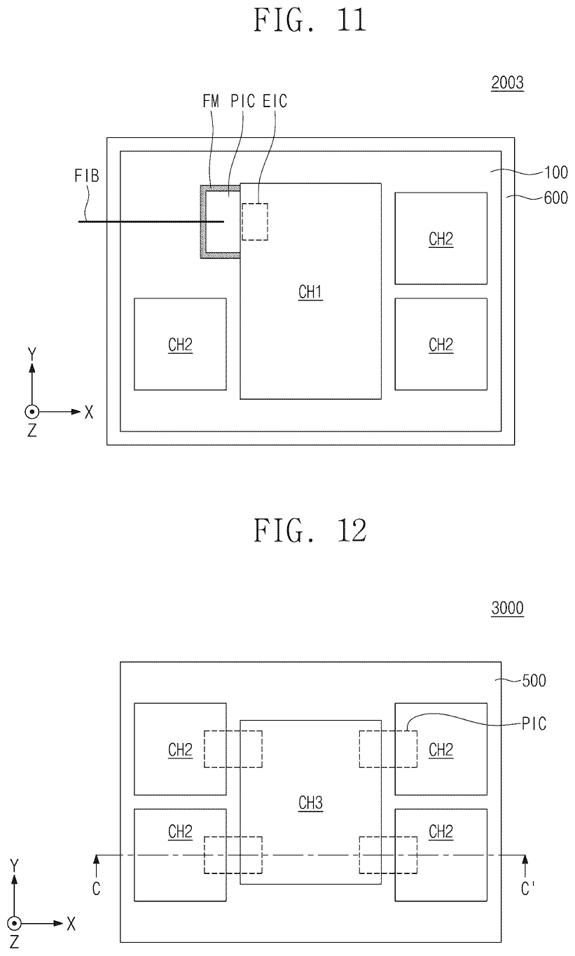

FIG. 11 is a plan view of a semiconductor package according to some implementations of the present disclosure.

Referring to FIG. 11, a semiconductor package 2003 has a structure in which an electronic integrated circuit region EIC is disposed on an edge extending in the second direction Y of the first semiconductor chip CH1. An optical die PIC may be bonded to a lower portion of the electronic integrated circuit region EIC of the first semiconductor chip CH1. The semiconductor package 2003 may include a package substrate 600. The package substrate 600 may be, for example, a double-sided or multi-layer printed circuit substrate. A semiconductor package 1000 may be disposed on the package substrate 600. In this example, one first semiconductor chip CH1 and three second semiconductor chips CH2 are disposed on the first substrate 100. The second semiconductor chips CH2 may be arranged on both sides of the first semiconductor chip CH1 in the first direction X. One of the second semiconductor chips CH2 may be arranged side by side and spaced apart from the optical die PIC. However, the arrangement of the second semiconductor chips CH2 is not limited thereto, and four or more second semiconductor chips CH2 may be included in the semiconductor package 2003. Other aspects of the semiconductor package 2003 may be the same as or similar to those described with reference to FIGS. 1 to 9B. It will be understood that the first semiconductor chip CH1 and the second semiconductor chips CH2 can have the configurations described for the first semiconductor chips CH1 and the second semiconductor chips CH2 of any one or more of the semiconductor packages 1000, 1001, 1002, and/or 1003.

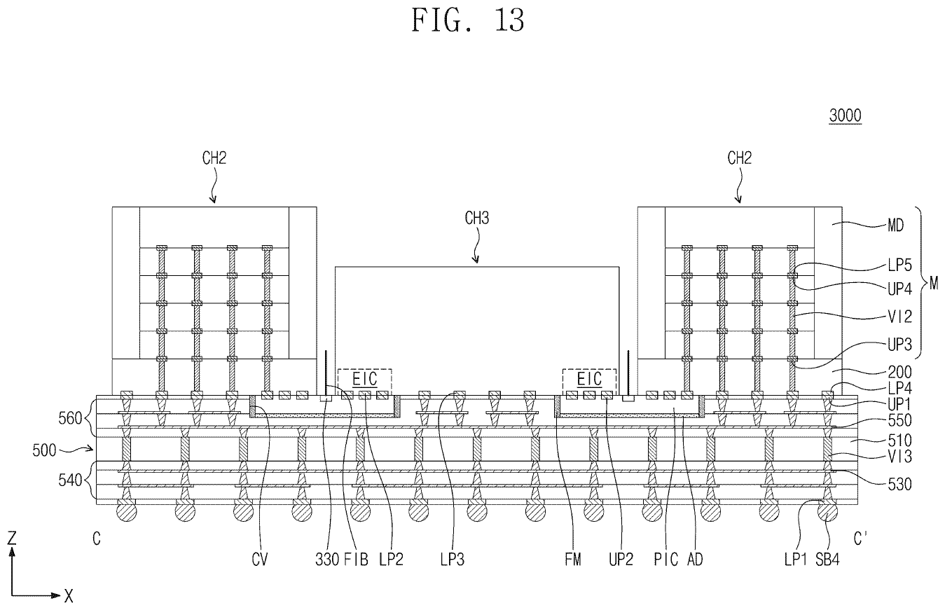

FIG. 12 is a plan view of a semiconductor package according to some implementations of the present disclosure. FIG. 13 is a cross-sectional view taken along line C-C′ of FIG. 12.

Referring to FIGS. 12 and 13, a semiconductor package 3000 includes a package substrate 500. Four second semiconductor chips CH2 and one third semiconductor chip CH3 may be disposed on the package substrate 500. Two second semiconductor chips CH2 may be disposed on each of two opposite sides of the third semiconductor chip CH3. Optical dies PIC may be disposed between the second semiconductor chip CH2 and the third semiconductor chip CH3, respectively. When viewed in a plan view, the optical dies PIC may overlap the second and third semiconductor chips CH2 and CH3.

Referring to FIGS. 12 and 13, the package substrate 500 may include a second substrate 510. The second substrate 510 may include an insulating material. The second substrate 510 may include, for example, one of glass fiber, ceramic plate, epoxy, and resin. In some implementations, the second substrate 510 may include one of stainless steel, aluminum (Al), nickel (Ni), magnesium (Mg), zinc (Zn), or tantalum (Ta).

First wiring patterns 530 may be sequentially disposed on a lower portion of the second substrate 510. A first insulating layer 540 covering the first wiring patterns 530 may be disposed under the second substrate 510. First lower conductive pads LP1 connected to the first wiring patterns 530 may be disposed under the first insulating layer 540. Fourth connection members SB4 may be bonded to the first lower conductive pads LP1. Second wiring patterns 550 may be sequentially disposed on the second substrate 510. A second insulating layer 560 covering the second wiring patterns 550 may be disposed on the second substrate 510. First upper conductive pads UP1 connected to the second wiring patterns 550 may be disposed on the second insulating layer 560.

Each of the first and second wiring patterns 530 and 550 may include one of copper (Cu), aluminum (Al), silver (Ag), tin (Sn), gold (Au), nickel (Ni), lead (Pb) or titanium (Ti). The first and second insulating layers 540 and 560 may each include prepreg, Ajinomoto build-up film (ABF), or bismaleimide triazine (BT). The fourth connection members SB4 may include metal, for example, at least one of copper, nickel, tin, lead, and silver.

Third through vias VI3 may be disposed to vertically penetrate the second substrate 510. The third through vias VI3 may be connected to the corresponding first and second wiring patterns 530 and 550, respectively. The third through vias VI3 may include metal such as copper, aluminum, or tungsten.

A plurality of cavities CV may be disposed on the second substrate 510. Bottom surfaces of the cavities CV may be disposed in the second insulating layer 560 and may not be connected to the second wiring patterns 550. The cavities CV may be arranged to be spaced apart from the second substrate 510. Optical dies PIC may be disposed in each cavity CV. The optical dies PIC may be identical or similar to the optical dies PIC described with reference to FIGS. 1 and 2. Each optical die PIC may include a connection portion 330 on an upper surface thereof. An optical fiber FIB may be connected to the connection portion 330. The optical die PIC may transmit and receive external optical signals through the connection portion 330. Second upper conductive pads UP2 may be disposed on the optical die PIC to be spaced apart from the connection portion 330. An adhesive member AD may be interposed between the optical dies PIC and the bottom surfaces of the cavities CV. A filling member FM may be interposed between the inner walls of the cavities CV and the optical dies PIC.

A third semiconductor chip CH3 may be disposed on the package substrate 500. Electronic integrated circuit regions EIC spaced apart in the first direction X may be disposed at lower edges of the third semiconductor chip CH3. Second lower conductive pads LP2 may be disposed below the electronic integrated circuit regions EIC. Third lower conductive pads LP3 may be disposed at the lower center of the third semiconductor chip CH3 and spaced apart from the second lower conductive pads LP2. Other aspects of the third semiconductor chip CH3 may be the same as or similar to those of the first semiconductor chip CH1 described with reference to FIGS. 1 and 2.

Some of the first upper conductive pads UP1 of the package substrate 500 may be in direct contact with the corresponding third lower conductive pads LP3 of the third semiconductor chip CH3. The first upper conductive pads UP1 of the package substrate 500 and the corresponding third lower conductive pads LP3 of the third semiconductor chip CH3 may include the same material. The first upper conductive pad UP1 of the package substrate 500 and the third lower conductive pad LP3 of the third semiconductor chip CH3 that are in contact with each other may be fused to form an integrated body.

Some of the second upper conductive pads UP2 of the optical die PIC may be in direct contact with the corresponding second lower conductive pads LP2 of the third semiconductor chip CH3. The second upper conductive pads UP2 of the optical die PIC and the corresponding second lower conductive pads LP2 of the third semiconductor chip CH3 may include the same material. The second upper conductive pad UP2 of the optical die PIC and the second lower conductive pad LP2 of the third semiconductor chip CH3 that are in contact with each other may be fused to form an integrated body.

The second semiconductor chips CH2 may be arranged on the package substrate 500 to be spaced apart from each other. The second semiconductor chips CH2 may be the same as or similar to the second semiconductor chips CH2 described with reference to FIGS. 1 and 2. The second semiconductor chips CH2 may include fourth lower conductive pads LP4 at lower portions thereof.

Some of the second upper conductive pads UP2 of the optical die PIC may be in direct contact with the corresponding fourth lower conductive pads LP4 of the second semiconductor chip CH2. The second upper conductive pads UP2 of the optical die PIC and the corresponding fourth lower conductive pads LP4 of the second semiconductor chip CH2 may include the same material. The second upper conductive pad UP2 of the optical die PIC and the fourth lower conductive pad LP4 of the second semiconductor chip CH2 that are in contact with each other may be fused to form an integrated body.

In some implementations, as the second and third semiconductor chips CH2 and CH3 are in direct contact with the package substrate 500 and the optical dies PIC, a signal transmission distance therebetween may be reduced, thereby improving operation speed of the semiconductor package 3000. As a result, a semiconductor package 3000 with optimized performance may be provided.

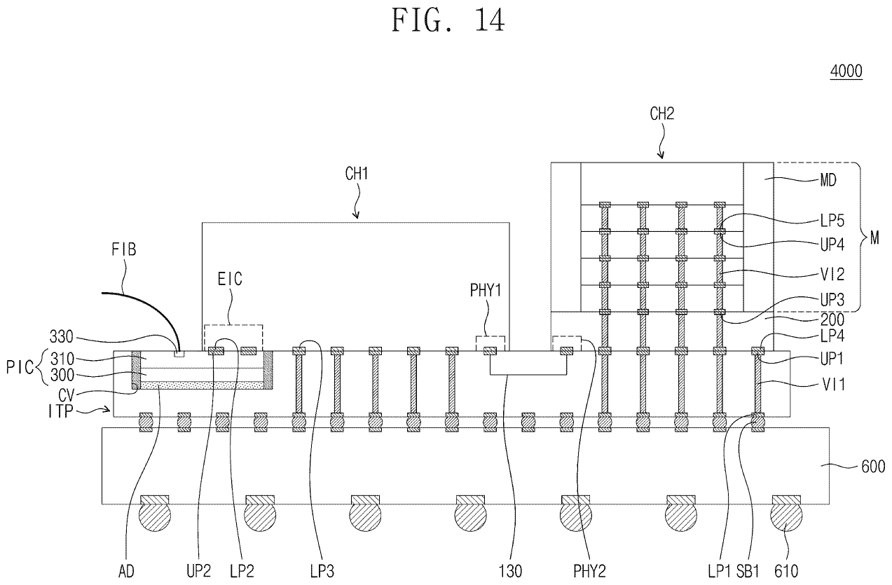

FIG. 14 is a cross-sectional view of a semiconductor package according to some implementations of the present disclosure.

Referring to FIG. 14, a semiconductor package 4000 has a structure in which a package substrate 600 is connected to a lower portion of an interposer ITP, in addition to the structure of FIG. 7. The package substrate 600 may be, for example, a double-sided or multi-layer printed circuit substrate. External connection members 610 may be bonded to a lower portion of the package substrate 600. The external connection members 610 may include metal, for example, at least one of copper, nickel, tin, lead, and silver. Other aspects of the semiconductor package 4000 may be the same as or similar to those described with reference to FIGS. 1 to 8.

Accordingly, in some implementations described herein, an optical die including a photonic integrated circuit (or optical integrated circuit) and a logic chip including an electronic integrated circuit may be directly bonded or may be bonded using hybrid Cu bonding, and a signal transmission distance may be reduced, thereby maintaining a low latency when the semiconductor package operates. Additionally, the area of the interposer substrate or the package substrate on which the semiconductor chips are mounted may be reduced and the semiconductor packages may be optically connected. Therefore, the operation speed of the semiconductor package may be improved, and the semiconductor package with the optimized performance may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples, a person skilled in the art may understand that many modifications and variations are made without departing from the spirit and scope of this disclosure.

What is claimed is:

1. A semiconductor package comprising:
a first substrate including
a first edge region, a center region, and a second edge region arranged in sequence along a first direction, and
a cavity in the first edge region;
an optical die in the cavity of the first substrate;
a first semiconductor chip including an electronic integrated circuit region at a lower portion of the first semiconductor chip, wherein the first semiconductor chip is disposed on the first substrate and the optical die; and
a plurality of second semiconductor chips disposed on the second edge region of the first substrate,
wherein the electronic integrated circuit region of the first semiconductor chip is disposed on the optical die and is electrically connected to the optical die.

2. The semiconductor package of claim 1, wherein the optical die includes first upper conductive pads disposed on an upper surface of the optical die,
wherein the first semiconductor chip includes first lower conductive pads and second lower conductive pads disposed on a lower surface of the first semiconductor chip,
wherein the first lower conductive pads are disposed in the electronic integrated circuit region and are in contact with the first upper conductive pads of the optical die,
wherein the second lower conductive pads are disposed on the center region, and
wherein the first upper conductive pads and the first lower conductive pads include a same material.

3. The semiconductor package of claim 2, wherein the first substrate includes second upper conductive pads disposed on an upper surface of the first substrate,
wherein a plurality of the second upper conductive pads are in contact with the second lower conductive pads of the first semiconductor chip, and
wherein the second upper conductive pads of the first substrate and the second lower conductive pads of the first semiconductor chip include the same material.

4. The semiconductor package of claim 2, wherein each of the first lower conductive pads of the first semiconductor chip has a first width, and
wherein each of the second lower conductive pads of the first semiconductor chip has a second width smaller than the first width.

5. The semiconductor package of claim 2, wherein each of the first upper conductive pads of the optical die has a width of 1 μm to 7 μm.

6. The semiconductor package of claim 1, comprising a filling member filling a space between the optical die and an inner wall of the cavity.

7. The semiconductor package of claim 6, wherein the filling member is interposed between the first substrate and the first semiconductor chip.

8. The semiconductor package of claim 6, wherein an upper surface of the optical die and an upper surface of the filling member are coplanar with each other.

9. The semiconductor package of claim 1, comprising an adhesive member interposed between a bottom surface of the cavity of the first substrate and the optical die.

10. The semiconductor package of claim 1, wherein the first semiconductor chip includes first physical layer regions spaced apart from the electronic integrated circuit region in the first direction,
wherein each of the second semiconductor chips includes a second physical layer region disposed at a lower portion of the second semiconductor chip, and
wherein the first substrate includes connection wiring connecting the first physical layer regions to the second physical layer regions.

11. The semiconductor package of claim 1, comprising connection members connecting an upper surface of the first substrate to lower surfaces of the second semiconductor chips.

12. The semiconductor package of claim 1, wherein the optical die includes:
a connection portion disposed at an upper portion of the optical die, wherein the connection portion is spaced apart from the first semiconductor chip, and
an optical fiber connected to the connection portion.

13. A semiconductor package comprising:
an interposer including a first edge region, a center region, and a second edge region arranged in sequence along a first direction;
a first semiconductor chip disposed on the interposer on the first edge region and the center region; and
a plurality of second semiconductor chips disposed on the interposer on the second edge region,
wherein the interposer includes:
a first substrate having a cavity in the first edge region,
an optical die disposed in the cavity,
first upper conductive pads disposed on an upper surface of the first substrate,
first lower conductive pads disposed on a lower surface of the first substrate,
first through vias extending through the first substrate and connecting the first upper conductive pads and the first lower conductive pads,
wherein the optical die includes:
second upper conductive pads disposed on an upper surface of the optical die, and
a connection portion disposed on the upper surface of the optical die and spaced apart from the second upper conductive pads,
wherein the first semiconductor chip includes:
an electronic integrated circuit region on the optical die,
second lower conductive pads disposed below the electronic integrated circuit region, and
third lower conductive pads disposed on the center region,
wherein each of the second semiconductor chips includes:
a buffer die including fourth lower conductive pads on a lower surface of the buffer die,
a plurality of memory dies sequentially stacked on the buffer die, and
second through vias extending through the buffer die and the memory dies,
wherein the second upper conductive pads of the optical die are in contact with the second lower conductive pads of the first semiconductor chip, and
wherein the second upper conductive pads of the optical die and the second lower conductive pads of the first semiconductor chip include a same material.

14. The semiconductor package of claim 13, wherein a plurality of the first upper conductive pads of the first substrate are in contact with the third lower conductive pads of the first semiconductor chip, and
wherein the first upper conductive pads of the first substrate and the third lower conductive pads of the first semiconductor chip include the same material.

15. The semiconductor package of claim 13, comprising a filling member filling a space between the optical die and an inner wall of the cavity.

16. The semiconductor package of claim 13, wherein the interposer includes an adhesive member interposed between the optical die and a bottom surface of the cavity.

17. The semiconductor package of claim 13, wherein a second plurality of the first upper conductive pads of the first substrate are in contact with the fourth lower conductive pads of the buffer die, and
wherein the second plurality of the first upper conductive pads of the first substrate and the fourth lower conductive pads of the buffer die include the same material.

18. The semiconductor package of claim 13, comprising external connection members bonded to the first lower conductive pads of the first substrate.

19. A semiconductor package comprising:
a first substrate including a first edge region, a center region, and a second edge region arranged sequentially along a first direction;
a chip structure disposed on the first substrate on the first edge region and the center region; and
a plurality of second semiconductor chips disposed on the first substrate on the second edge region,
wherein the first substrate includes:
a cavity in an upper portion of the first substrate in the first edge region, and
first upper conductive pads disposed on an upper surface of the first substrate,
wherein the chip structure includes:
a first semiconductor chip, and
an optical die bonded to a lower portion of the first semiconductor chip on the first edge region and arranged in the cavity, and
wherein a first level of an upper surface of the optical die is higher than a second level of the upper surface of the first substrate.

20. The semiconductor package of claim 19, wherein a lower surface of the first semiconductor chip is spaced apart from the first substrate, and
wherein the semiconductor package includes a filling member interposed between the optical die and an inner wall of the cavity, between the optical die and a bottom surface of the cavity, and between the first semiconductor chip and the first substrate.
